(19) United States
(12) Patent Application Publication
(10) Pub. No.: US 2026/0196766 A1
(43) Pub. Date: Jul. 9, 2026

(54) CONNECTOR DEVICE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Makoto MASHITA, Mie (JP); Takuya IWAMOTO, Mie (JP); Masakatsu MORIGUCHI, Mie (JP)

(21) Appl. No.: 19/134,747

(22) PCT Filed: Nov. 15, 2023
(86) PCT No.: PCT/JP2023/041014

§ 371 Date: Jun. 2, 2025

(30) Foreign Application Priority Data
Dec. 6, 2022 (JP) 2022-194611

(51) Int. Cl. H01R 13/533; H01R 13/6581

(52) U.S. Cl. CPC H01R 13/533; H01R 13/6581

(57) ABSTRACT

The present invention makes it easier to dissipate heat of an IC included in a connector. A connector device (1) comprises a circuit board (10), a connector (20) disposed on the circuit board (10), and a housing (70) that accommodates at least portions of the circuit board (10) and the connector (20). The connector (20) has a sub board (35), an IC (36) mounted to the sub board (35), and a heat transfer part (for example, a heat dissipation sheet (39) and a shield cover (38)) that transfers the heat of the IC (36) to the housing (70).

### TECHNICAL FIELD

The present disclosure relates to a connector device.

### BACKGROUND

Patent Document 1 discloses a board connector to be disposed on a circuit board.

### PRIOR ART DOCUMENT

### Patent Document

Patent Document 1: JP 2021-061188 A

### SUMMARY OF THE INVENTION

### Problems to be Solved

In the case of incorporating an IC (Integrated Circuit) into a connector of this type, the heat generation of the IC becomes problematic.

The present disclosure aims to provide a technique facilitating the escape of heat of an IC incorporated in a connector.

### Means to Solve the Problem

The present disclosure is directed to a connector device with a circuit board, a connector to be disposed on the circuit board, and a housing for accommodating the circuit board and at least a part of the connector, the connector including a sub-board, an IC to be mounted on the sub-board and a heat transfer portion for transferring heat of the IC to the housing.

### Effect of the Invention

According to the connector device of the present disclosure, the escape of the heat of the IC incorporated in the connector can be facilitated.

### BRIEF DESCRIPTION OF THE DRAWINGS

FIG. 1 is a perspective view of a connector device of a first embodiment.

FIG. 2 is an exploded perspective view of the partially cut connector device.

FIG. 3 is an exploded perspective view of a relay connector portion.

FIG. 4 is an exploded perspective view of a housing.

FIG. 5 is a plan view in section of the connector device cut by a plane passing through a fastening part by bolts.

FIG. 6 is a section along A-A of FIG. 5.

FIG. 7 is a section along B-B of FIG. 5.

FIG. 8 is a plan view in section of a connector device in a second embodiment cut by a plane passing through the fastening part by the bolts.

FIG. 9 is a section, corresponding to FIG. 7, of a connector device in a third embodiment.

FIG. 10 is a section along C-C of FIG. 9.

FIG. 11 is a section, corresponding to FIG. 7, of a connector device in a fourth embodiment.

FIG. 12 is a section along D-D of FIG. 11.

FIG. 13 is a section, corresponding to FIG. 6, of a connector device in a fifth embodiment.

FIG. 14 is a section along E-E of FIG. 13.

### DETAILED DESCRIPTION TO EXECUTE THE INVENTION

### Description of Embodiments of Present Disclosure

First, embodiments of the present disclosure are listed and described.
[1] The connector device of the present disclosure is provided with a circuit board, a connector to be disposed on the circuit board, and a housing for accommodating the circuit board and at least a part of the connector, the connector including a sub-board, an IC to be mounted on the sub-board and a heat transfer portion for transferring heat of the IC to the housing.

According to this configuration, the heat of the IC can be allowed to escape to the housing via the heat transfer portion.
[2] In the connector device of [1], the connector includes a shield cover for covering the IC, and the shield cover constitutes at least a part of the heat transfer portion.

According to this configuration, the heat of the IC can be allowed to escape to the housing, utilizing the shield cover for covering the IC.
[3] In the connector device of [2], the housing includes an opening, the shield cover includes an extending portion extending to outside of the housing via the opening and a cover-side protruding portion spreading along an outer surface of the housing from a tip part of the extending portion, and the cover-side protruding portion is fixed to the outer surface of the housing using a bolt.

According to this configuration, the cover-side protruding portion can be fixed to the housing using the bolt from the outside of the housing. In this way, the cover-side protruding portion is pressed against the housing, and the heat is more easily transferred from the shield cover to the housing.
[4] In the connector device of [3], the connector includes an outer conductor to be fixed to the outer surface of the housing, and the outer conductor and the cover-side protruding portion are fastened together to the outer surface of the housing using the bolt.

According to this configuration, the shield cover can be pressed against the housing, utilizing a configuration for fixing the outer conductor to the housing.
[5] In the connector device of [2], the shield cover includes a resilient contact piece to be resiliently deformed and is arranged in a state pressed against the housing by a resilient force of the resilient contact piece.

According to this configuration, the shield cover is pressed against the housing, and the heat is more easily transferred from the shield cover to the housing.
[6] In the connector device of [1], the connector includes an outer conductor constituting at least a part of the heat transfer portion.

According to this configuration, the heat of the IC can be allowed to escape to the housing, utilizing the outer conductor of the connector.
[7] In the connector device of any one of [1] to [6], the heat transfer portion is made of metal.

According to this configuration, the heat of the IC is even more easily transferred to the housing.
[8] In the connector device of any one of [1] to [7], the connector includes a mounted connector portion to be mounted on the circuit board and a relay connector portion to be connected to the mounted connector portion, and the sub-board and the IC are provided on the relay connector portion.

According to this configuration, by preparing a plurality of relay connector portions including different types of ICs installed thereon, connectors corresponding to a plurality of types of communication specifications can be configured according to the types of the relay connector portions to be connected to the mounted connector portions.

### Details of Embodiments of Present Disclosure

Specific examples of the present disclosure are described below with reference to the drawings. Note that the present invention is not limited to these illustrations, but is represented by claims and intended to include all changes in the scope of claims and in the meaning and scope of equivalents.

### First Embodiment

### (Summary of Connector Device 1)

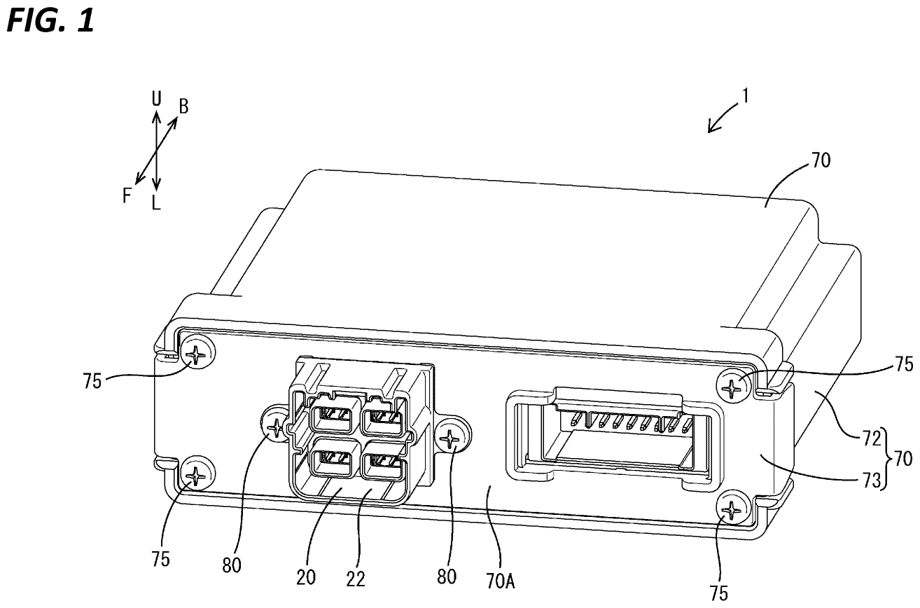

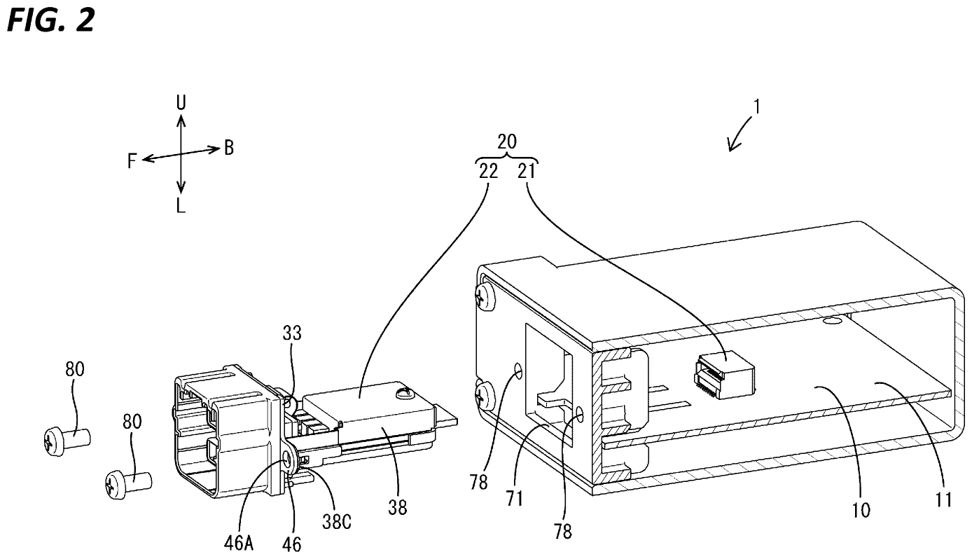

A connector device 1 of a first embodiment is shown in FIG. 1. The connector device 1 is, for example, installed in a vehicle. As shown in FIG. 2, the connector device 1 is provided with a circuit board 10, a connector 20 to be disposed on the circuit board 10 and a housing 70 for accommodating the circuit board 10 and at least a part of the connector 20.

In this embodiment, a side where the connector 20 is disposed on the circuit board 10 is defined as an upper side. A side where an unillustrated mating connector is connected to the connector 20 is defined as a front side. A direction orthogonal to a vertical direction and a front-back direction is defined as a width direction. In figures, “U”, “L”, “F” and “B” denote the upper side, a lower side, the front side and a back side.

### (Circuit Board 10)

As shown in FIG. 2, the circuit board 10 is plate-like. A plate thickness direction of the circuit board 10 is the vertical direction. The circuit board 10 is formed with a mounting surface 11. The mounting surface 11 is formed on the upper surface of the circuit board 10.

### (Connector 20)

The connector 20 is a board connector to be disposed on the circuit board 10. As shown in FIG. 2, the connector 20 includes a mounted connector portion 21 to be mounted on the circuit board 10 and a relay connector portion 22 to be connected to the mounted connector portion 21.

As shown in FIG. 2, the mounted connector portion 21 is, for example, configured as a card edge connector. The relay connector portion 22 is detachably connected to the mounted connector portion 21. An insertion groove is formed in the front surface of the mounted connector portion 21. By inserting the relay connector portion 22 into this insertion groove from front, the relay connector portion 22 is connected to the mounted connector portion 21.

The unillustrated mating connector is connected to the relay connector portion 22. A plurality of types of relay connector portions 22 are prepared, for example, in accordance with the number of devices installed in the vehicle and communication specifications (e.g. a communication speed and the like). By connecting the relay connector portion 22 corresponding to specifications of the vehicle, in which the relay connector portion 22 is installed, to the mounted connector portion 21, the connector device 1 can be compatible with a plurality of types of vehicles.

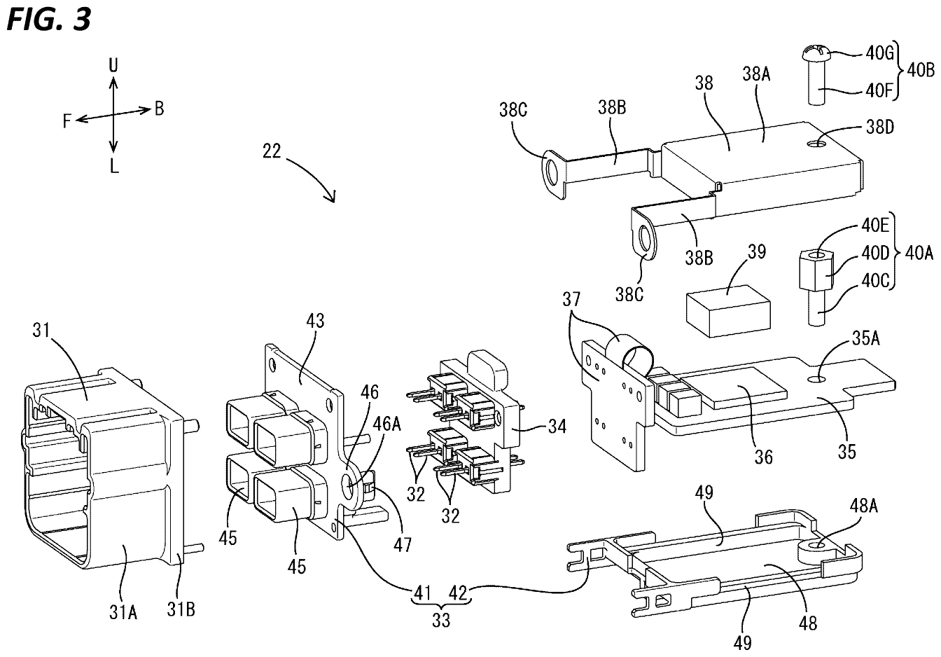

As shown in FIG. 3, the relay connector portion 22 includes a fitting member 31, inner conductors 32, an outer conductor 33, a dielectric 34, a sub-board 35, an IC (Integrated Circuit) 36, a relay portion 37, a shield cover 38, a heat dissipation sheet 39, a first fixing member 40A and a second fixing member 40B.

As shown in FIG. 3, the fitting member 31 is fit to the unillustrated mating connector. The fitting member 31 is insulating and, for example, made resin. The fitting member 31 includes a receptacle 31A in the form of a rectangular tube and a back wall portion 31B covering the back surface of the receptacle 31A.

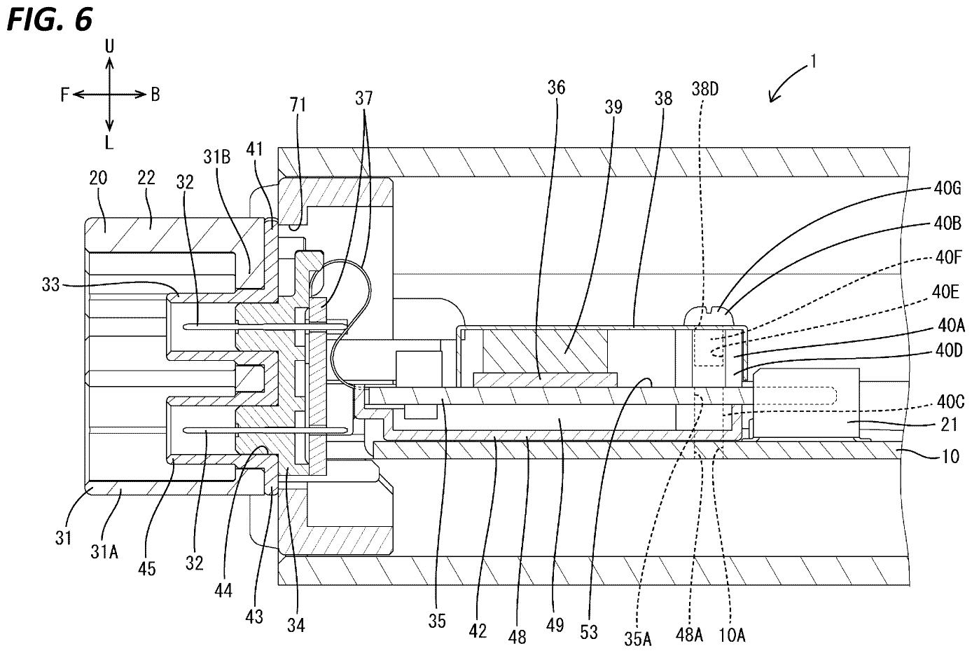

The inner conductor 32 is electrically conductive and, for example, made of metal. As shown in FIG. 3, the inner conductor 32 extends in the front-back direction. A plurality of the inner conductors 32 are provided at intervals in a direction orthogonal to the front-back direction. As shown in FIG. 6, front end parts of the inner conductors 32 project into the receptacle 31, and back end parts of the inner conductors 32 project further backward than the back wall portion 31B. The inner conductors 32 are electrically connected to an electrically conductive path of the sub-board 35 via the relay portion 37.

The outer conductor 33 is electrically conductive and, for example, made of metal. As shown in FIG. 3, the outer conductor 33 includes a first outer conductor member 41 and a second outer conductor member 42. The second outer conductor member 42 is coupled to the first outer conductor member 41 by being locked to the first outer conductor member 41.

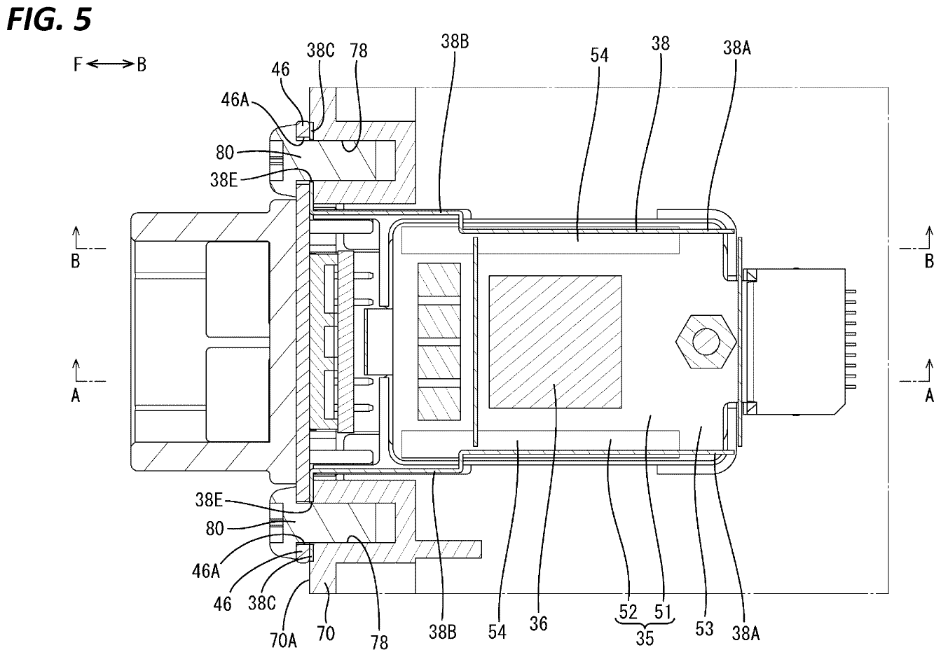

The first outer conductor member 41 covers the outer peripheries of the inner conductors 32. The first outer conductor member 41 includes a wall portion 43 having a thickness in the front-back direction. The wall portion 43 is formed with inner conductor insertion holes 44, through which the inner conductors 32 are inserted. The first outer conductor member 41 includes tube portions 45 having a tubular shape and projecting forward from peripheral edge parts of the inner conductor insertion holes 44. The tube portion 45 projects into the receptacle 31A through the back wall portion 31B of the fitting member 31. As shown in FIG. 5, the first outer conductor member 41 includes outer conductor-side protruding portions 46 to be fixed to the housing 70. The outer conductor-side protruding portions 46 protrude toward both widthwise sides from vertical centers of both widthwise sides of the wall portion 43. The outer conductor-side protruding portion 46 spreads along an outer surface 70A of the housing 70. The outer conductor-side protruding portion 46 is formed with a through hole 46A, through which a bolt 80 is passed. The outer conductor-side protruding portion 46 is fixed to the housing 70, using the bolt 80. As shown in FIG. 3, the first outer conductor member 41 includes a locking portion 47 for locking the second outer conductor member 42. The locking portion 47 is provided at a position backward of the wall portion 43.

The second outer conductor member 42 is locked by the locking portion 47 and arranged behind the first outer conductor member 41. As shown in FIGS. 3 and 6, the second outer conductor member 42 includes an outer conductor bottom portion 48 and placing portions 49 rising upward from both widthwise sides of the outer conductor bottom portion 48. The outer conductor bottom portion 48 is plate-like. A plate thickness direction of the outer conductor bottom portion 48 is the vertical direction. The sub-board 35 is placed to be supported by the placing portions 49 on both widthwise sides. The second outer conductor member 42 and the sub-board 35 are fixed to the circuit board 10 by the aforementioned first fixing member 40A. The first fixing member 40A includes an externally threaded portion 40C, a head portion 40D provided on a base end part of the externally threaded portion 40C and an internally threaded portion 40E formed to be recessed in the base end part of the head portion 40D. The externally threaded portion 40C is inserted through the insertion hole 35A of the sub-board 35 and the insertion hole 48A of the outer conductor bottom portion 48 and screwed and tightened into a mounting hole 10A of the circuit board 10. In this way, the sub-board 35 and the second outer conductor member 42 are fixed to the circuit board 10.

As shown in FIG. 6, the dielectric 34 is arranged between the inner conductors 32 and the outer conductor 33.

As shown in FIG. 6, the sub-board 35 is plate-like. The sub-board 35 is arranged in parallel to the circuit board 10. A plate thickness direction of the sub-board 35 is the vertical direction. The sub-board 35 is a board to be incorporated into the connector 20. The sub-board 35 is detachably connected to the mounted connector portion 21. The sub-board 35 includes a sub-board body 51 and a sub-ground circuit 52 as shown in FIG. 5.

As shown in FIG. 3, the sub-board body 51 is plate-like. The sub-board body 51 is insulating and, for example, made of resin. The sub-board body 51 is formed with a sub-mounting surface 53. The sub-mounting surface 53 is formed on the upper surface of the sub-board body 51.

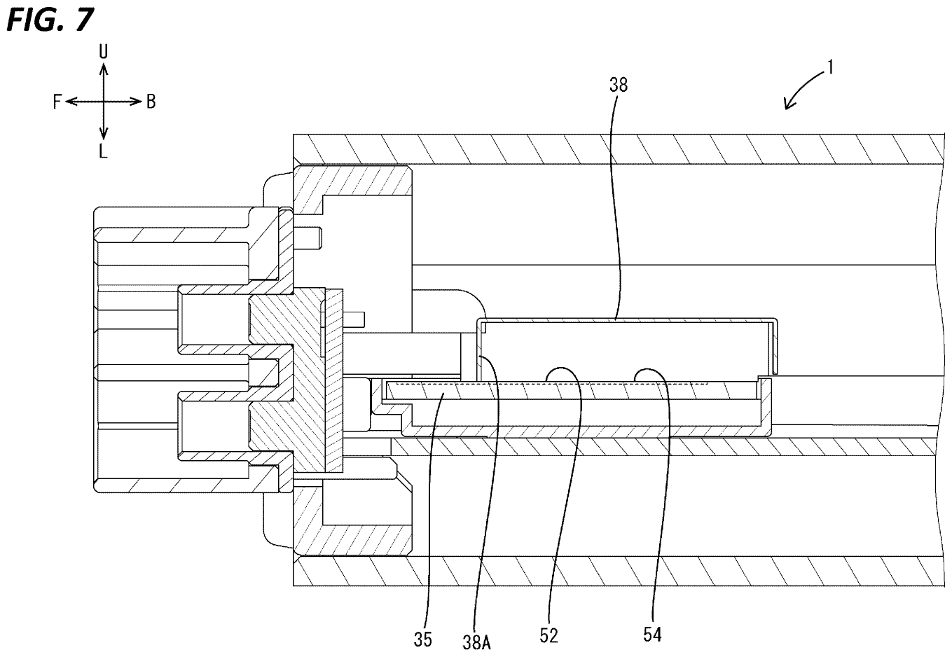

As shown in FIGS. 5 and 7, the sub-ground circuit 52 is provided on the sub-board body 51 (more specifically, the sub-mounting surface 53). The IC 36 mounted on the sub-mounting surface 53 is electrically connected to the sub-ground circuit 52. The sub-ground circuit 52 includes sub-extension circuits 54 extending in the front-back direction along the sub-mounting surface 53. A plurality of the sub-extension circuits 54 are provided at an interval in the width direction.

The IC 36 is configured by resin-molding an IC chip. As shown in FIG. 6, the IC 36 is mounted on the sub-mounting surface 53 (upper surface) of the sub-board 35.

The shield cover 38 is electrically conductive and, for example, made of metal. The shield cover 38 is, for example, formed by bending a metal material. As shown in FIGS. 3 and 5, the shield cover 38 includes a cover body 38A, a pair of extending portions 38B and a pair of cover-side protruding portions 38C. The cover body 38A covers the IC 36 from above. Further, the cover body 38A covers the IC 36 from the front-back direction and the width direction. The pair of extending portions 38B are formed to extend forward from both widthwise sides of the cover body 38A. The pair of cover-side protruding portions 38C protrude away from each other in the width direction from front end parts of the pair of extending portions 38B.

The heat dissipation sheet 39 is made of resin such as silicon or acrylic resin. As shown in FIG. 6, the heat dissipation sheet 39 is arranged in a state vertically sandwiched between the IC 36 and the shield cover 38. The heat dissipation sheet 39 is arranged in contact with the IC 36 and the shield cover 38.

As shown in FIG. 3, the second fixing member 40B includes an externally threaded portion 40F and a head portion 40G provided on a base end part of the externally threaded portion 40F. As shown in FIG. 6, the externally threaded portion 40F is inserted through the insertion hole 38D of the shield cover 38 from above and screwed and tightened into the internally threaded portion 40E of the first fixing member 40A. In this way, the shield cover 38 is fixed to the sub-board 35.

### (Housing 70)

The housing 70 is electrically conductive and, for example, made of metal. As shown in FIG. 1, the housing 70 is box-shaped. As shown in FIGS. 2 and 6, the housing 70 accommodates the circuit board 10 and a part of the connector 20. The housing 70 includes an opening 71. The relay connector portion 22 is inserted into the housing 70 via the opening 71 and connected to the mounted connector portion 21 mounted on the circuit board 10.

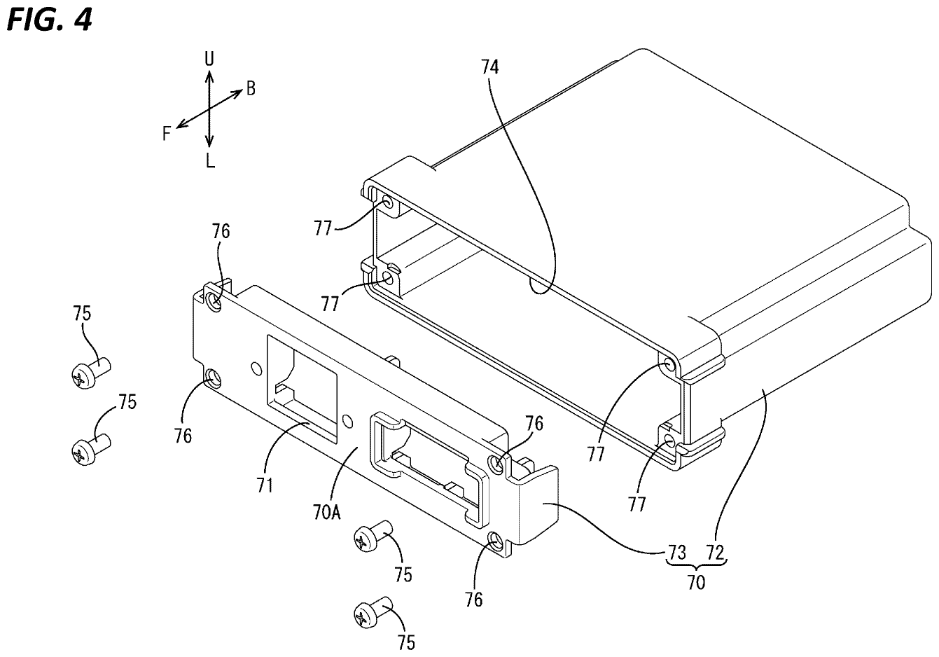

As shown in FIG. 4, the housing 70 includes a housing body 72 and a cover 73. The housing body 72 accommodates the circuit board 10 and a part of the connector 20. The housing body 72 is formed with a board insertion opening 74. The circuit board 10 is inserted into the housing body 72 through the board insertion opening 74.

As shown in FIGS. 1 and 4, the cover 73 covers the board insertion opening 74. The cover 73 is fixed to the housing body 72. The cover 73 is fixed to the housing body 72 using bolts 75 for housing. A plurality of (four in this embodiment) the bolts 75 for housing are inserted through insertion holes 76 at a plurality of positions (four positions in this embodiment) and screwed and tightened into housing-side mounting holes 77 of the housing body 72. The cover 73 is provided with the aforementioned opening 71.

As shown in FIG. 5, the relay connector portion 22 inserted through the opening 71 is fixed to the outer surface 70A of the housing 70 using the bolts 80. Mounting holes 78 are formed in the outer surface 70A of the housing 70. The mounting holes 78 are provided on both widthwise sides of the opening 71. The pair of cover-side protruding portions 38C of the shield cover 38 are arranged behind the pair of outer conductor-side protruding portions 46. Each cover-side protruding portion 38C is formed with a through hole 38E penetrating through the cover-side protruding portion 38C in the front-back direction. Each outer conductor-side protruding portion 46 is formed with a through hole 46A penetrating through the outer conductor-side protruding portion 46 in the front-back direction. The through hole 38E and the through hole 46A are arranged side by side in the front-back direction. The bolt 80 is passed through the through holes 46A, 38E and screwed and tightened into the mounting hole 78. In this way, the outer conductor 33 and the cover-side protruding portion 38C are fastened together to the outer surface 70A of the housing 70.

### (Functions and Effects of Connector Device 1)

As shown in FIG. 6, the IC 36 is in contact with the heat dissipation sheet 39, and the shield cover 38 is in contact with the heat dissipation sheet 39. As shown in FIG. 5, the extending portions 38B of the shield cover 38 extend to the outside of the housing 70 through the opening 71. The cover-side protruding portions 38C protruding from the extending portions 38B are fixed to the outer surface of the housing 70 using the bolts 80. Thus, the heat of the IC 36 is transferred to the housing 70 via the heat dissipation sheet 39 and the shield cover 38. Accordingly, according to this configuration, the heat of the IC 36 can be allowed to escape to the housing 70 via the heat dissipation sheet 39 and the shield cover 38. Further, by fixing the cover-side protruding portions 38C to the housing 70 using the bolts 80, the cover-side protruding portions 38C are pressed against the housing 70. Thus, the heat is more easily transferred from the shield cover 38 to the housing 70. Moreover, the cover-side protruding portions 38C are fastened to the housing 70 together with the outer conductor 33. That is, according to this configuration, the shield cover 38 can be pressed against the housing 70, utilizing a configuration for fixing the outer conductor 33 to the housing 70.

Further, the IC 36 is electrically connected to the sub-ground circuit 52. As shown in FIG. 7, the sub-extension circuits 54 of the sub-ground circuit 52 are electrically connected to the cover body 38A of the shield cover 38. As shown in FIG. 6, the shield cover 38 is electrically connected to the housing 70 by the cover-side protruding portions 38C being fixed to the housing 70 using the bolts 80. Thus, the heat of the IC 36 is transferred to the housing 70 via the sub-ground circuit 52 and the shield cover 38. Therefore, according to this configuration, the heat of the IC 36 can be allowed to escape to the housing 70 via the sub-ground circuit 52 and the shield cover 38. Moreover, the sub-ground circuit 52 and the shield cover 38 are made of metal. Thus, the heat of the IC 36 is even more easily transferred to the housing 70.

### Second Embodiment

In a second embodiment, a configuration for bringing a shield cover into contact with the inner surface of a housing is described. Note that, in the description of the second embodiment, the same components as in the first embodiment are denoted by the same reference signs and are not described in detail.

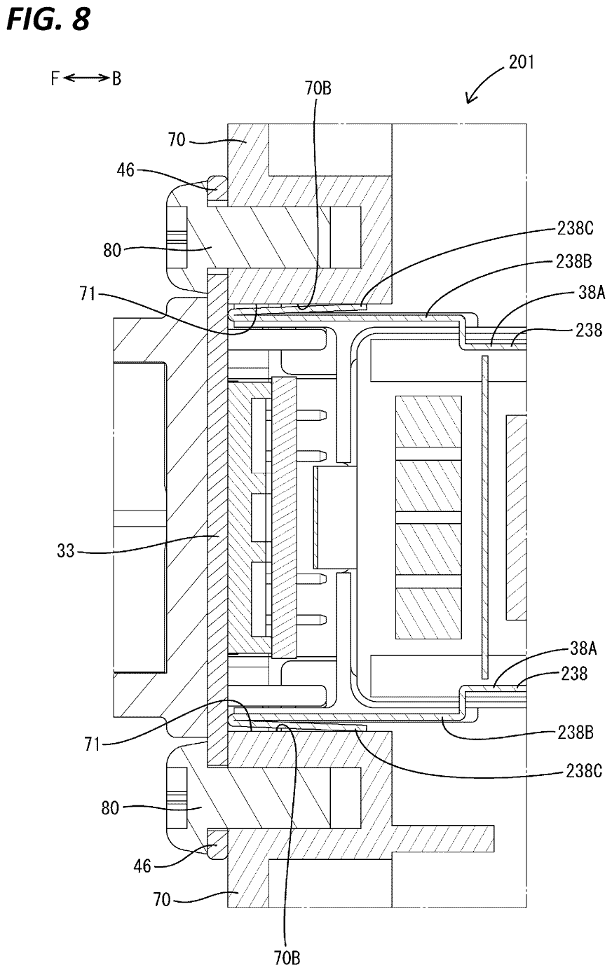

A connector device 201 of the second embodiment is, as shown in FIG. 8, provided with a shield cover 238 instead of the shield cover 38 of the first embodiment. The connector device 201 of the second embodiment is otherwise common to the connector device 1 of the first embodiment.

The shield cover 238 is electrically conductive and, for example, made of metal. The shield cover 238 is, for example, formed by bending a metal material. The shield cover 238 includes a cover body 38A, a pair of arm portions 238B and a pair of resilient contact pieces 238C. The pair of arm portions 238B extend forward from both widthwise sides of the cover body 38A. The pair of resilient contact pieces 238C are folded outward in the width direction from tip parts of the pair of arm portions 238B. Each resilient contact piece 238C is cantilevered and supported on each arm portion 238B, and deflected and deformed in the width direction with each arm portion 238B as a fulcrum.

The shield cover 238 is inserted into an opening 71 of a housing 70 while deflecting the pair of resilient contact pieces 238B inward in the width direction. With the shield cover 238 inserted in the opening 71, the pair of resilient contact pieces 238C are deformed to be expanded outward in the width direction by resilient forces and press the inner peripheral surface of the opening 71. That is, the resilient contact pieces 238C are pressed against an inner surface 70B of the housing 70.

As described above, in the connector device 201 of the second embodiment, the resilient contact pieces 238C of the shield cover 38 are in contact with the inner surface 70B of the housing 70. According to this configuration, heat of an IC 36 transferred to the shield cover 238 can be allowed to escape to the housing 70. Moreover, the resilient contact pieces 238C are arranged in a state pressed against the housing 70 by resilient forces of the resilient contact pieces 238C. According to this configuration, heat is more easily transferred from the shield cover 238 to the housing 70.

### Third Embodiment

In a third embodiment, another configuration for bringing a shield cover into contact with the inner surface of a housing is described. Note that, in the description of the third embodiment, the same components as in the first embodiment are denoted by the same reference signs and are not described in detail.

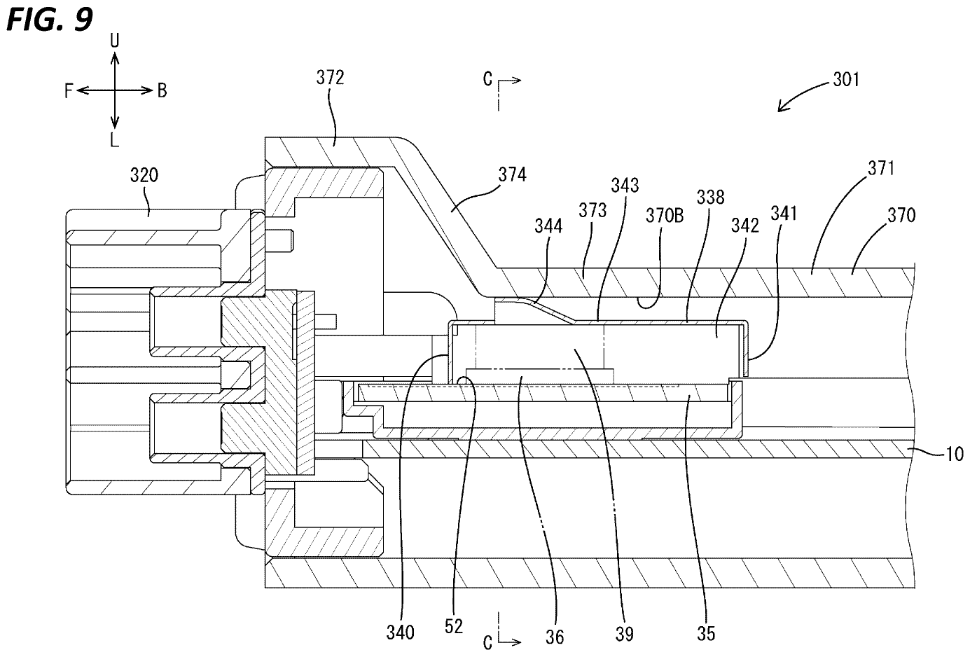

A connector device 301 of the third embodiment is, as shown in FIG. 9, provided with a circuit board 10, a connector 320 to be disposed on the circuit board 10 and a housing 370 for accommodating the circuit board 10 and a part of the connector 320. The connector 320 differs from the connector 20 of the first embodiment in including a shield cover 338 instead of the shield cover 38, and is otherwise common. The housing 370 is different from the housing 70 of the first embodiment in that a ceiling wall 371 is stepped, and is otherwise common.

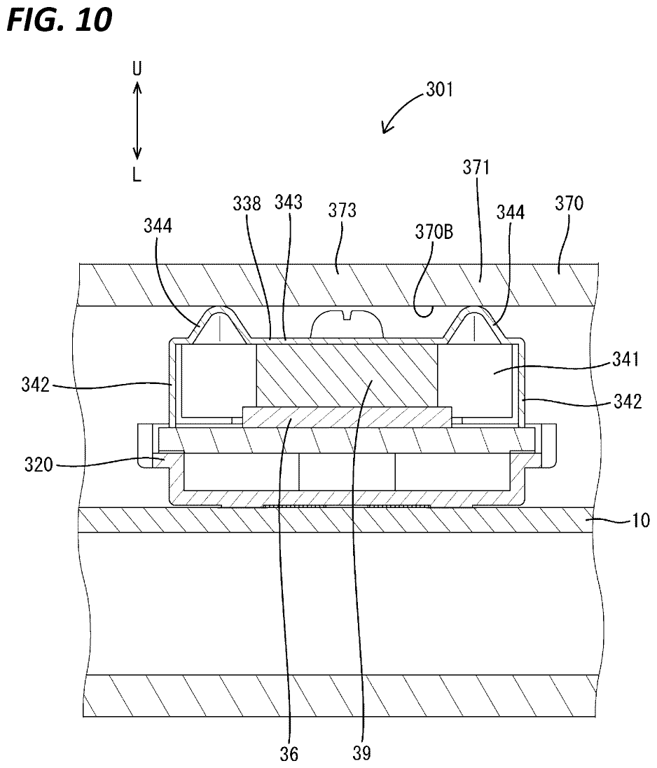

The shield cover 338 is electrically conductive and, for example, made of metal. The shield cover 338 is, for example, formed by bending a metal material. As shown in FIGS. 9 and 10, the shield cover 338 covers an IC 36 from above. The shield cover 338 includes a front plate portion 340, a back plate portion 341, a pair of side plate portions 342, a ceiling plate portion 343 and projecting portions 344. The front plate portion 340 covers a front side of the IC 36. The back plate portion 341 covers a back side of the IC 36. The pair of side plate portions 342 cover both widthwise sides of the IC. The ceiling plate portion 343 covers an upper side of the IC 36. The ceiling plate portion 343 is connected to an upper end part of each of the front plate portion 340, the back plate portion 341 and the pair of side plate portions 342. The projecting portions 344 project upward from the ceiling plate portion 343. The projecting portions 344 are provided on both widthwise sides of the ceiling plate portion 343. The projecting portions 344 are formed, for example, by cutting and raising the metal plate.

The ceiling wall 371 of the housing 370 includes a first ceiling wall portion 372, a second ceiling wall portion 373 and a step portion 374. The second ceiling wall portion 373 is connected to the first ceiling wall portion 372 via the step portion 374 and arranged at a position lower than the first ceiling wall portion 372. The projecting portions 344 are in contact with the lower surface of the second ceiling wall portion 373. That is, the shield cover 338 is in contact with an inner surface 370B of the housing 370.

As shown in FIG. 9, a heat dissipation sheet 39 is sandwiched between the ceiling plate portion 343 of the shield cover 338 and the IC 36. The heat dissipation sheet 39 is arranged in contact with the ceiling plate portion 343 of the shield cover 338 and the IC 36. Heat of the IC 36 is transferred to the shield cover 338 via the heat dissipation sheet 39.

As shown in FIG. 9, the front plate portion 340 of the shield cover 338 is electrically connected to a sub-ground circuit 52. Thus, the heat of the IC 36 is transferred to the shield cover 338 via the sub-ground circuit 52.

The heat transferred to the shield cover 338 is transferred to the housing 370 from the projecting portions 344. That is, according to the connector device 301 of the third embodiment, the heat can be allowed to escape to the inner surface 370B of the housing 370, utilizing the shield cover 338.

### Fourth Embodiment

In a fourth embodiment, a configuration enabling heat of an IC to escape to a housing without utilizing a shield cover is described. Note that, in the description of the fourth embodiment, the same components as in the first embodiment are denoted by the same reference signs and are not described in detail.

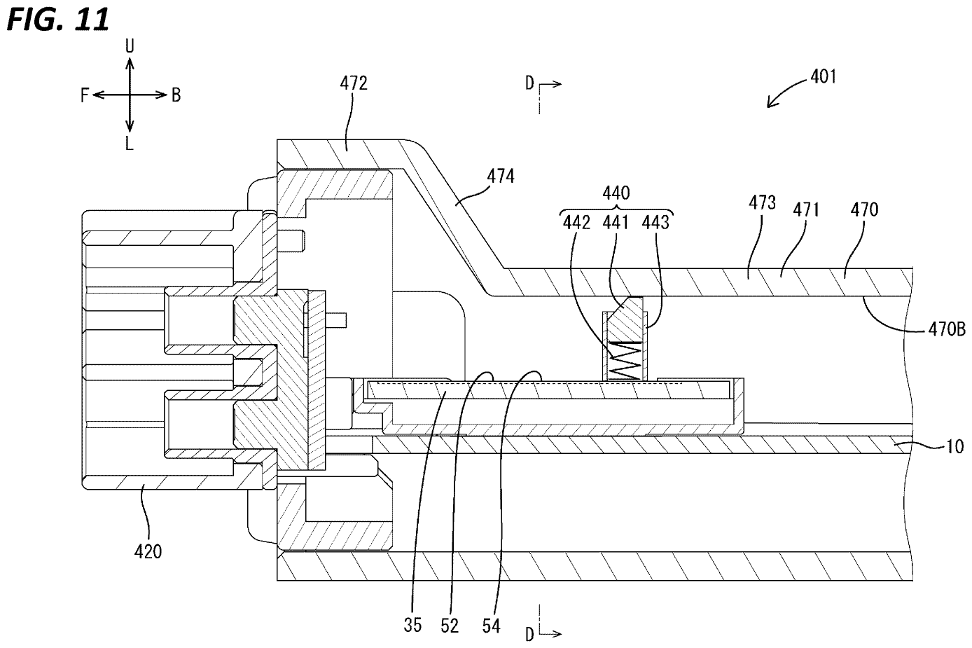

A connector device 401 of the fourth embodiment is, as shown in FIG. 11, provided with a circuit board 10, a connector 420 to be disposed on the circuit board 10 and a housing 470 for accommodating the circuit board 10 and a part of the connector 420. The connector 420 differs from the connector 20 of the first embodiment in including electrically conductive members 440 instead of the shield cover 38, and is otherwise common. The housing 470 is different from the housing 70 of the first embodiment in that a ceiling wall 471 is stepped, and is otherwise common.

The ceiling wall 471 of the housing 470 includes a first ceiling wall portion 472, a second ceiling wall portion 473 and a step portion 474. The second ceiling wall portion 473 is connected to the first ceiling wall portion 472 via the step portion 474 and arranged at a position lower than the first ceiling wall portion 472.

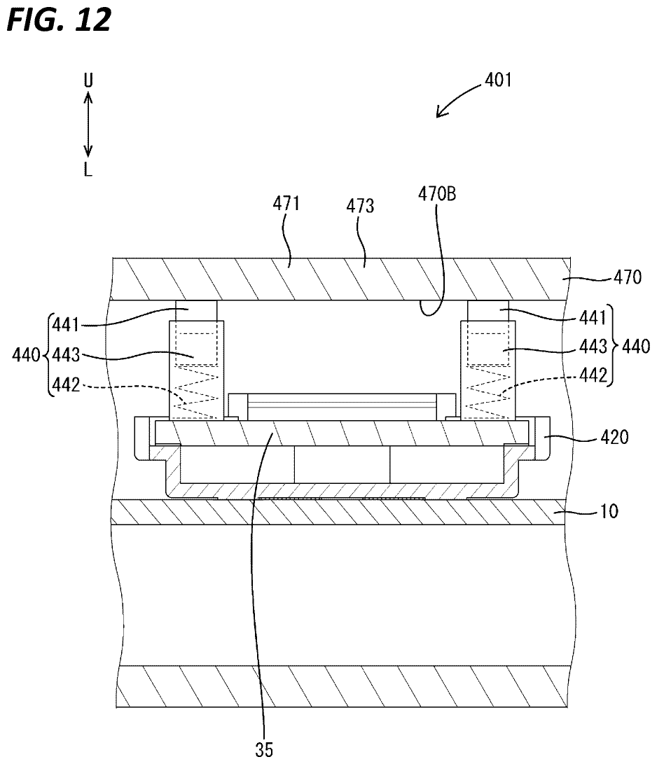

As shown in FIG. 12, the electrically conductive members 440 are provided on respective sub-extension circuits 54 on both widthwise sides. Each electrically conductive member 440 is arranged between a sub-ground circuit 52 of a sub-board 35 and the second ceiling wall portion 473 and electrically connected to the sub-ground circuit 52 and the second ceiling wall portion 473. The electrically conductive member 440 includes a contacting electrically conductive portion 441 for contacting the second ceiling wall portion 473, a biasing member 442 to be arranged between the contacting electrically conductive portion 441 and the sub-ground circuit 52 and a guide portion 443 for guiding the contacting electrically conductive portion 441 in the vertical direction. The biasing member 442 is, for example, a spring member and biases the contacting electrically conductive portion 441 in a direction separating from the sub-ground circuit 52. The contacting electrically conductive portion 441 is pressed against the second ceiling wall portion 473. That is, the electrically conductive member 440 is pressed against the sub-ground circuit 52 and an inner surface 470B of the housing 470.

As described above, in the connector device 401 of the fourth embodiment, an IC 36 is electrically connected to the sub-ground circuit 52. The electrically conductive members 440 are in contact with the sub-ground circuit 52, and the housing 470 is in contact with the electrically conductive members 440. According to this configuration, heat of the IC 36 can be allowed to escape to the housing 470 via the sub-ground circuit 52 and the electrically conductive members 440. Moreover, the electrically conductive members 440 are pressed against the sub-ground circuit 52 and the housing 470. According to this configuration, the heat of the IC 36 is more easily transferred to the housing 470 via the sub-ground circuit 52 and the electrically conductive members 440.

### Fifth Embodiment

In a fifth embodiment, a configuration enabling heat of an IC to escape to a housing utilizing an outer conductor of a connector is described. Note that, in the description of the fifth embodiment, the same components as in the first embodiment are denoted by the same reference signs and are not described in detail.

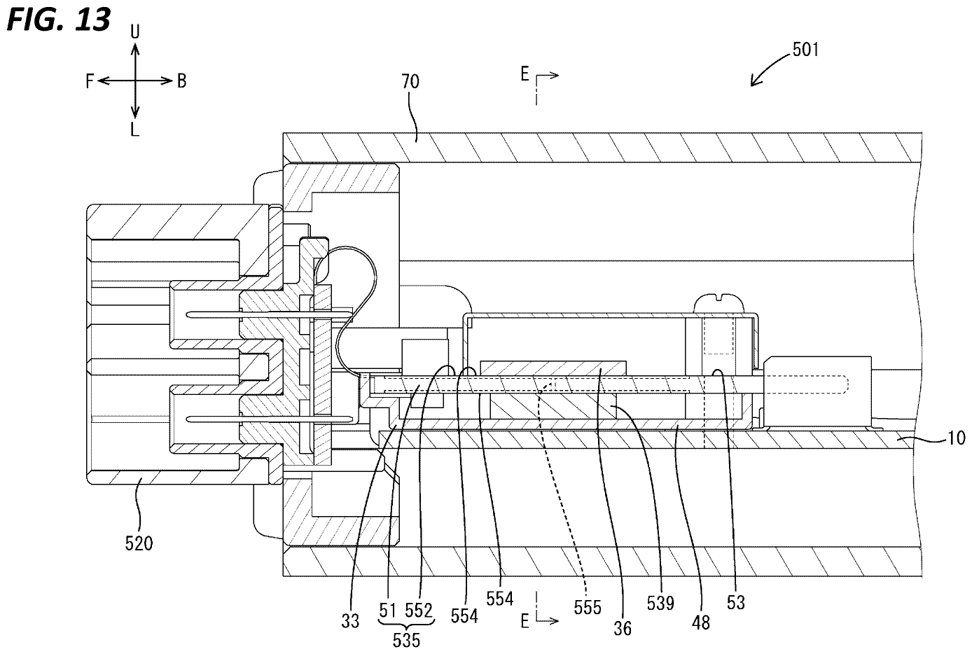

A connector device 501 of the fifth embodiment is, as shown in FIG. 13, provided with a circuit board 10, a connector 520 to be disposed on the circuit board 10 and a housing 70 for accommodating the circuit board 10 and a part of the connector 520.

The connector 520 is common to the connector 20 of the first embodiment in including a sub-board 535 instead of the sub-board 35, including a heat dissipation sheet 539 instead of the heat dissipation sheet 39 and fixing outer conductor-side protruding portions 46 of an outer conductor 33 singly to the housing 70. The connector 52 is otherwise common to connector 20 of the first embodiment.

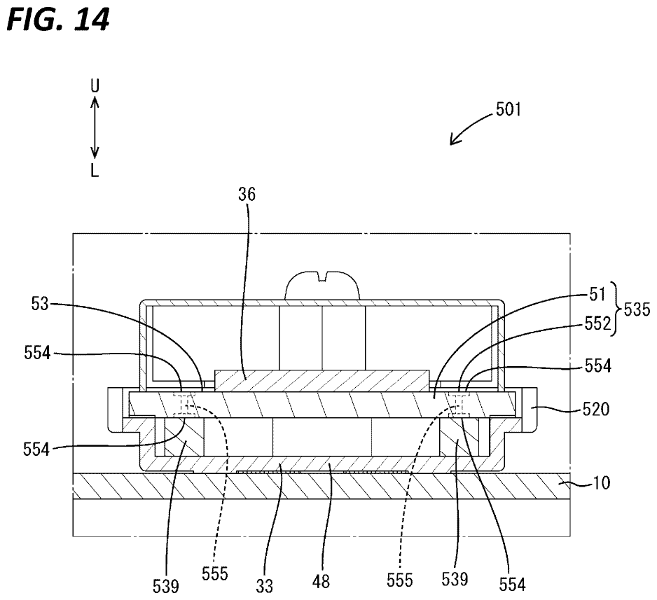

As shown in FIGS. 13 and 14, the sub-board 535 includes a sub-board body 51 and a sub-ground circuit 552. The sub-ground circuit 552 is provided on the sub-board body 51 (more specifically, a sub-mounting surface 53). An IC 36 mounted on the sub-mounting surface 53 is electrically connected to the sub-ground circuit 552. The sub-ground circuit 552 includes sub-extension circuits 554 extending in the front-back direction along the sub-mounting surface 53. A plurality of the sub-extension circuits 554 are provided at an interval in the width direction. The sub-extension circuits 554 are provided on both upper and lower surfaces of the sub-board body 51. The sub-extension circuits 554 on the both upper and lower surfaces are electrically connected through via holes 555 penetrating through the sub-board body 51 in a plate thickness direction.

The heat dissipation sheet 539 is provided between the sub-extension circuits 554 provided on the lower surface of the sub-board body 51 and the upper surface of an outer conductor bottom portion 48 of an outer conductor 33 and in contact with the sub-extension circuits 554 and the outer conductor bottom portion 48.

The outer conductor-side protruding portions 46 of the outer conductor 33 are fixed to the housing 70 using bolts 80 (see FIG. 8). In this way, the outer conductor 33 is in contact with the housing 70 while being pressed against the housing 70.

As described above, in the connector device 501 of the fifth embodiment, the IC 36 is electrically connected to the sub-ground circuit 552. The sub-ground circuit 552 is in contact with the heat dissipation sheet 539, and the heat dissipation sheet 539 is in contact with the outer conductor 33. The outer conductor 33 is in contact with the housing 70. According to this configuration, heat of the IC 36 can be allowed to escape to the housing 70 via the sub-ground circuit 552, the heat dissipation sheet 539 and the outer conductor 33. Moreover, the outer conductor-side protruding portions 46 of the outer conductor 33 are pressed against the housing 70. According to this configuration, heat of the outer conductor 33 is easily transferred to the housing 70.

### OTHER EMBODIMENT OF PRESENT DISCLOSURE

The embodiments disclosed this time should be considered illustrative in all aspects, rather than restrictive.
(1) Although the mounted connector portion and the relay connector portion are separate from each other in the connector in each of the above embodiments, a mounted connector portion and a relay connector portion may be integrated.

List of Reference Numerals

| | |
|---|---|
| 1 | connector device |
| 10 | circuit board |
| 10A | mounting hole |
| 11 | mounting surface |
| 20 | connector |
| 21 | mounted connector portion |
| 22 | relay connector portion |
| 31 | fitting member |
| 31A | receptacle |
| 31B | back wall portion |
| 32 | inner conductor |
| 33 | outer conductor |
| 34 | dielectric |
| 35 | sub-board |
| 35A | insertion hole |
| 36 | IC |
| 37 | relay portion |
| 38 | shield cover |
| 38A | cover body |
| 38B | extending portion |
| 38C | cover-side protruding portion |
| 38D | insertion hole |
| 38E | through hole |
| 39 | heat dissipation sheet |
| 40A | first fixing member |
| 40B | second fixing member |
| 40C | externally threaded portion |
| 40D | head portion |
| 40E | internally threaded portion |
| 40F | externally threaded portion |
| 40G | head portion |
| 41 | first outer conductor member |
| 42 | second outer conductor member |
| 43 | wall portion |
| 44 | inner conductor insertion hole |
| 45 | tube portion |
| 46 | outer conductor-side protruding portion |
| 46A | through hole |
| 47 | locking portion |
| 48 | outer conductor bottom portion |
| 48A | insertion hole |
| 49 | placing portion |
| 51 | sub-board body |
| 52 | sub-ground circuit |
| 53 | sub-mounting surface |
| 54 | sub-extension circuit |
| 70 | housing |
| 70A | outer surface |
| 70B | inner surface |
| 71 | opening |
| 72 | housing body |
| 73 | cover |
| 74 | board insertion opening |
| 75 | bolt for housing |
| 76 | insertion hole |
| 77 | housing-side mounting hole |
| 78 | mounting hole |
| 80 | bolt |
| 201 | connector device |
| 238 | shield cover |
| 238B | arm portion |
| 238C | resilient contact piece |
| 301 | connector device |
| 320 | connector |
| 338 | shield cover |
| 340 | front plate portion |
| 341 | back plate portion |
| 342 | side plate portion |
| 343 | ceiling plate portion |
| 344 | projecting portion |
| 370 | housing |
| 370B | inner surface |
| 371 | ceiling wall |
| 372 | first ceiling wall portion |
| 373 | second ceiling wall portion |
| 374 | step portion |
| 401 | connector device |
| 420 | connector |
| 440 | electrically conductive member |
| 441 | contacting electrically conductive member |
| 442 | biasing member |
| 443 | guide portion |
| 470 | housing |
| 470B | inner surface |
| 471 | ceiling wall |
| 472 | first ceiling wall portion |
| 473 | second ceiling wall portion |
| 474 | step portion |
| 501 | connector device |
| 520 | connector |
| 535 | sub-board |
| 539 | heat dissipation sheet |
| 552 | sub-ground circuit |
| 554 | sub-extension circuit |
| 555 | via hole |

1. A connector device, comprising:
a circuit board;
a connector to be disposed on the circuit board; and
a housing for accommodating the circuit board and at least a part of the connector.
the connector including a sub-board, an IC to be mounted on the sub-board and a heat transfer portion for transferring heat of the IC to the housing.

2. The connector device of claim 1, wherein:
the connector includes a shield cover for covering the IC, and
the shield cover constitutes at least a part of the heat transfer portion.

3. The connector device of claim 2, wherein:
the housing includes an opening.
the shield cover includes an extending portion extending to outside of the housing via the opening and a cover-side protruding portion spreading along an outer surface of the housing from a tip part of the extending portion, and
the cover-side protruding portion is fixed to the outer surface of the housing using a bolt.

4. The connector device of claim 3, wherein:
the connector includes an outer conductor to be fixed to the outer surface of the housing, and
the outer conductor and the cover-side protruding portion are fastened together to the outer surface of the housing using the bolt.

5. The connector device of claim 2, wherein the shield cover includes a resilient contact piece to be resiliently deformed and is arranged in a state pressed against the housing by a resilient force of the resilient contact piece.

6. The connector device of claim 1, wherein the connector includes an outer conductor constituting at least a part of the heat transfer portion.

7. The connector device of claim 1, wherein the heat transfer portion is made of metal.

8. The connector device of claim 1, wherein:
the connector includes a mounted connector portion to be mounted on the circuit board and a relay connector portion to be connected to the mounted connector portion, and
the sub-board and the IC are provided on the relay connector portion.
